(19) United States
(12) Patent Application Publication
(10) Pub. No.: US 2026/0267373 A1
(43) Pub. Date: Sep. 10, 2026

(54) WEARABLE DEVICE

(71) Applicant: HUAQIN TECHNOLOGY CO., LTD., Shanghai (CN)

(72) Inventors: WEIWEI CHENG, Shanghai (CN); PENGYU GAO, Shanghai (CN); DEHAI HU, Shanghai (CN)

(21) Appl. No.: 18/869,422

(22) PCT Filed: Aug. 31, 2023
(86) PCT No.: PCT/CN2023/116303

§ 371 Date: Nov. 26, 2024

(30) Foreign Application Priority Data
Sep. 22, 2022 (CN) 202211158168.6

(51) Int. Cl. G06F 1/16; H05K 5/02

(52) U.S. Cl. CPC G06F 1/163; H05K 5/0217

(57) ABSTRACT

A wearable device includes a device body provided with an accommodating cavity having an inner side surface in a first direction, a first matching member slidably arranged in the accommodating cavity in a second direction and having a side end surface in the first direction, a spring leaf disposed between the side end surface of the first matching member and the inner side surface of the accommodating cavity and configured to provide a reset decomposition force in the second direction, and a device fixing band provided with a second matching member configured to run through the accommodating cavity in a third direction to be engaged with the first matching member. The wearable device has the advantages of reasonably utilizing a lateral direction of the wearable device and reducing a longitudinal length of the wearable device.

### BACKGROUND

### 1. Technical Field

The present application relates to the technical field of wearable devices, and more specifically relates to a wearable device.

### 2. Background of the Invention

The wearable device is a portable device that can be worn directly or integrated into clothing or accessories of a user.

In the existing art, watches, wristbands, and the like all belong to wearable devices, and may each include a display portion and a binding portion. The display portion is configured to display information such as time, a count of steps and the like, while the binding portion typically has a belt shape for binding the display portion to a user.

However, a joint between the binding portion and the display portion often occupies large longitudinal space of the display portion, which may affect the appearance of the display portion unfavorably.

### SUMMARY

Embodiments of the present application provide a wearable device which can solve the problem of the joint between the binding portion and the display portion that occupies large longitudinal space of the display portion and affects the appearance of the display portion unfavorably.

To achieve the above object, the present application provides the following technical solutions.

In one aspect, an embodiment of the present application provides a wearable device, including: a device body provided with an accommodating cavity having an inner side surface in a first direction; a first matching member slidably arranged in the accommodating cavity in a second direction and having a side end surface in the first direction; a spring leaf disposed between the side end surface of the first matching member and the inner side surface of the accommodating cavity and configured to provide a reset decomposition force in the second direction; and a device fixing band provided with a second matching member configured to run through the accommodating cavity in a third direction to be engaged with the first matching member; where the first direction, the second direction and the third direction are intersected in a pairwise manner.

In one possible implementation, the spring leaf has a fixed end and a free end along the first direction, one of the side end surface of the first matching member and the inner side surface of the accommodating cavity is fixed to the fixed end of the spring leaf, while the other of the side end surface of the first matching member and the inner side surface of the accommodating cavity abuts against the free end of the spring leaf; and the one of the side end surface of the first matching member and the inner side surface of the accommodating cavity which abuts against the free end of the spring leaf is inclined relative to the second direction.

In one possible implementation, when the side end surface of the first matching member is fixed to the fixed end of the spring leaf, at least part of the inner side surface of the accommodating cavity abuts against the free end of the spring leaf, and is inclined toward a forward direction of the second direction and an outside of the accommodating cavity.

In one possible implementation, the free end of the spring leaf is located on a side of the fixed end of the spring leaf in the forward direction of the second direction.

In one possible implementation, the spring leaf and the first matching member are processed into a unitary piece through an integral molding process.

In one possible implementation, a joint between the fixed end of the spring leaf and the first matching member is provided with an arc surface having a center arranged in a forward direction of the second direction.

In one possible implementation, when the inner side surface of the accommodating cavity is fixed to the fixed end of the spring leaf, at least part of the side end surface of the first matching member abuts against the free end of the spring leaf, and is inclined toward a forward direction of the second direction and an outside of the accommodating cavity.

In one possible implementation, the free end of the spring leaf is located on a side of the fixed end of the spring leaf in a backward direction of the second direction, and the spring leaf is inclined in the same direction as the at least part of the side end surface of the first matching member.

In one possible implementation, the first matching member includes a body part and a beam part, the body part has an opening at an end in the second direction, and the beam part extends in the first direction to be disposed into the opening in the body part, and forms a through slot with the body part; and the second matching member is configured to run through the through slot of the first matching member to be engaged with the beam part.

In one possible implementation, an end surface of the beam part away from the through slot is provided with a reinforcing rib extending in the first direction.

The wearable device provided in the embodiment of the present application includes a device body, a first matching member and a device fixing band, where the device body is provided with an accommodating cavity having an inner side surface in a first direction; the first matching member is slidably arranged in the accommodating cavity in a second direction and has a side end surface in the first direction; and the device fixing band is provided with a second matching member that can run through the accommodating cavity in a third direction to be engaged with the first matching member. By providing a spring leaf between the side end surface of the first matching member and the inner side surface of the accommodating cavity, a reset decomposition force in the second direction can be provided by the spring leaf. Compared with an elastic member arranged in a longitudinal direction in the existing art, the spring leaf of the present application has the advantages of reasonably utilizing a lateral direction of the wearable device and reducing a longitudinal length of the wearable device.

In addition to the technical problems solved by the embodiments of the present application, the technical features constituting the technical solutions, and the beneficial effects brought by the technical features of the technical solutions described above, other technical problems that can be solved by the embodiments of the present application, other technical features included in the technical solutions, and beneficial effects brought by the technical features will be further described in detail below in the specific implementations.

### BRIEF DESCRIPTION OF THE DRAWINGS

FIG. 1 is an exploded view of a wearable device according to an embodiment of the present application;

FIG. 2 is a transverse section view of a first matching member of the wearable device shown in FIG. 1 in a first position;

FIG. 3 is a longitudinal section view of a first matching member of the wearable device shown in FIG. 1 in the first position;

FIG. 4 is a transverse section view of a first matching member of the wearable device shown in FIG. 1 in a second position;

FIG. 5 is a longitudinal section view of a first matching member of the wearable device shown in FIG. 1 in the second position;

FIG. 6 is a front view of a first matching member of the wearable device shown in FIG. 1;

FIG. 7 is a side view of a device fixing band of the wearable device shown in FIG. 1;

FIG. 8 is a schematic diagram of a wearable device in the existing art;

FIG. 9 is a diagram of resolution of forces at a free end of the first matching member shown in FIG. 4;

FIG. 10 is a partial schematic diagram of another wearable device according to an embodiment of the present application; and

FIG. 11 is a diagram of resolution of forces at a free end of the first matching member shown in FIG. 10.

### DETAILED DESCRIPTION

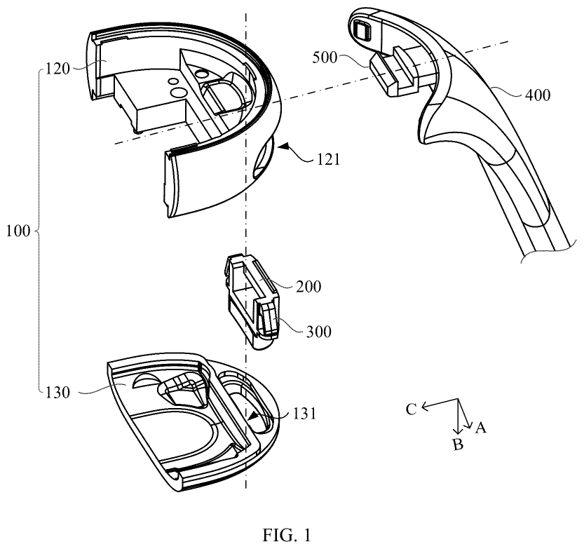

FIG. 1 is a partial exploded view of a wearable device according to an embodiment of the present application. Referring to FIG. 1, the wearable device may have a first direction A, a second direction B, and a third direction C intersected in a pairwise manner. In addition, the wearable device provided in the embodiment of the present application may include a device body 100 and a device fixing band 400. FIG. 1 illustrates a wearable device as a watch. The device body 100 may be a display portion such as a dial of the watch, and the device fixing band 400 may be a binding portion such as a band of the watch. Apparently, the wearable device provided in the embodiment of the present application may also be a wristband or glasses, or any other device having two detachable portions, and FIG. 1 is merely provided as an example and not intended to limit the present application specifically thereto.

In addition, to facilitate quick assembly of the device body 100 and the device fixing band 400, the wearable device may further include a first matching member 200 on the device body 100 and a second matching member 500 on the device fixing band 400. In other words, the device body 100 may be detachably connected to the device fixing band 400 through the first matching member 200, so that the device body 100 or the device fixing band 400 can be replaced conveniently.

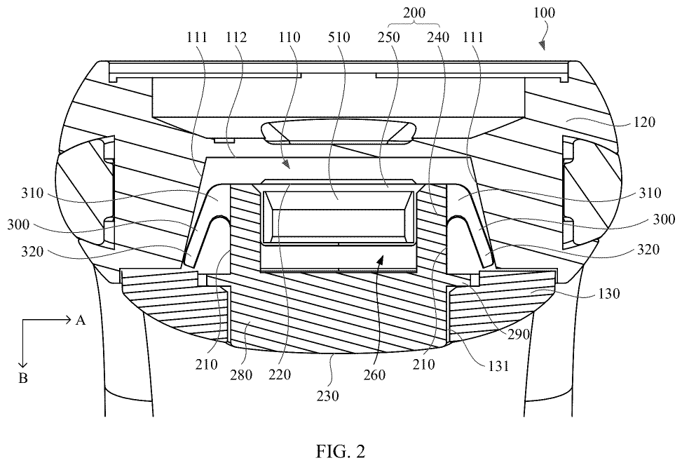

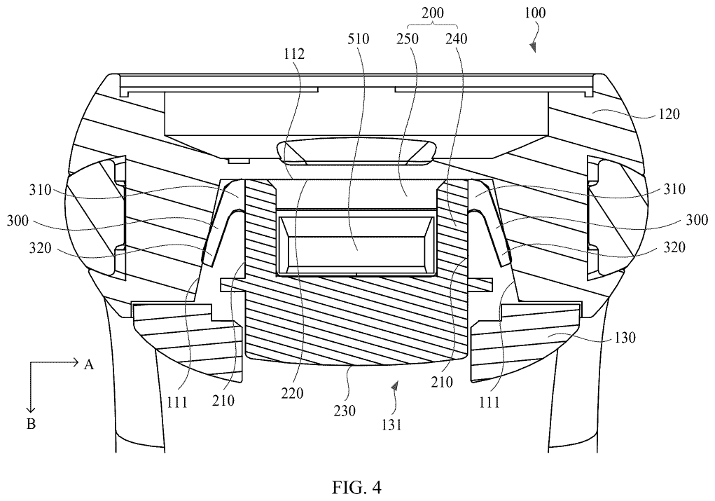

Referring to FIG. 2, the device body 100 may be provided with an accommodating cavity 110. Referring to FIGS. 1 and 2, the device body 100 may further have a through hole 131. The through hole 131 may be disposed at an end of the device body 100 in the second direction B and in communication with the accommodating cavity 110. The first matching member 200 may be inserted into the accommodating cavity 110 through the through hole 131. At least part of the first matching member 200 may be slidably disposed in an inner cavity of the through hole 131, so that the first matching member 200 in the accommodating cavity 110 can move in the accommodating cavity 110 along an axis (in the second direction B) of the through hole 131, and so that the first matching member 200 can have a first position shown in FIG. 2 and a second position shown in FIG. 4.

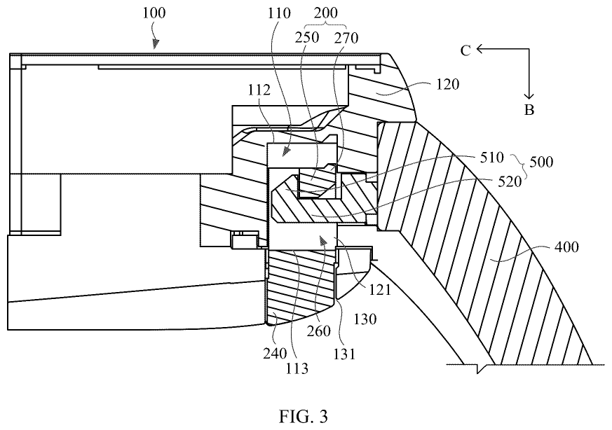

With continuing reference to FIG. 1, the device body 100 may have a mounting opening 121 in the third direction C. FIG. 3 is a longitudinal section view of a first matching member 200 of the wearable device shown in FIG. 1 in the first position. Referring to FIG. 3, the mounting opening 121 is in communication with the accommodating cavity 110, and the second matching member 500 on the device fixing band 400 can run through the mounting opening 121. In other words, the second matching member 500 can be inserted into the accommodating cavity 110 through the mounting opening 121.

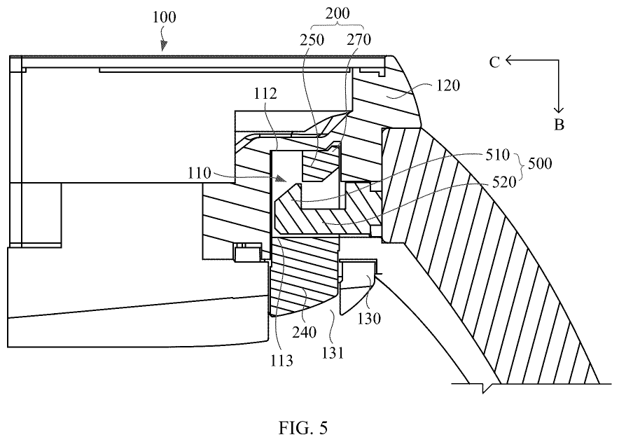

In addition, in the first position shown in FIGS. 2 and 3, the first matching member 200 is engaged with the second matching member 500, so that the device body 100 is fixed to the device fixing band 400. Apparently, in the second position shown in FIGS. 4 and 5, the first matching member 200 is separated from the second matching member 500, so that the device body 100 is separable from the device fixing band 400.

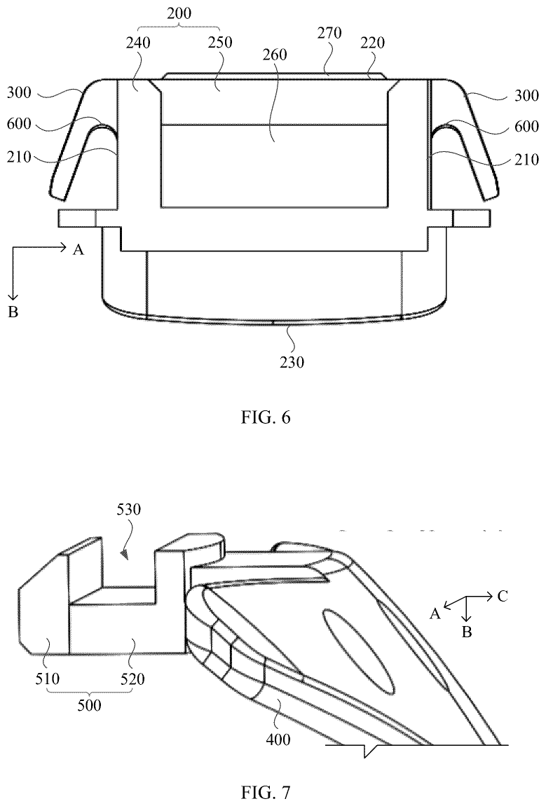

FIG. 6 is a front view of a first matching member 200 of the wearable device shown in FIG. 1, and FIG. 7 is a side view of a device fixing band 400 of the wearable device shown in FIG. 1. The following describes possible snap-fit manners of the first matching member 200 and the second matching member 500 with reference to FIGS. 1 to 7. Optionally, in a forward direction of the second direction B, the first matching member 200 may include a beam part 250, a body part 240, and a bottom part 280 connected in sequence. The body part 240 may be provided with an opening at an end in a backward direction of the second direction B. The beam part 250 may extend in the first direction A to be disposed into the opening in the body part 240, and may form a through slot 260 running through the first matching member 200 with the body part 240.

In addition, the second matching member 500 may include a first portion 510 and a second portion 520. The second portion 520 may extend in the third direction C and have a first end and a second end in the third direction C. A first end of the second portion 520 may be connected to the device fixing band 400, while a second end of the second portion 520 may be connected to the first portion 510. The first portion 510 may extend in the second direction B.

Referring to FIG. 3, when the second matching member 500 is engaged with the first matching member 200, the second matching member 500 is inserted into the through slot 260 in a forward direction (the direction indicated by arrow C) of the third direction C. The first portion 510 of the second matching member 500 may extend beyond the through slot 260. An end surface of the first portion 510 in a backward direction (a direction opposite to the direction indicated by arrow C) of the third direction C abuts against an end surface of the beam part 250 in the forward direction of the third direction C. An end surface of the second portion 520 of the second matching member 500 in a backward direction of the second direction B abuts against an end surface of the beam part 250 in the forward direction of the second direction B. In other words, the beam part 250 is restricted within a limiting slot 530 (see FIG. 7) formed by the first portion 510 and the second portion 520 of the second matching member 500.

To increase the strength of the beam part 250 to resist a pulling force in the third direction C, optionally, referring to FIGS. 3, 5 and 6, an end surface of the beam part 250 away from the through slot 260 is provided with a reinforcing rib 270 extending in the first direction A, so that the strength of the beam part 250 is increased by local thickening.

To keep the first matching member 200 at the first position shown in FIGS. 2 and 3 when the first matching member 200 is engaged with the second matching member 500, referring to FIGS. 2 and 3, the first matching member 200 may be limited by a wall of the through hole 131 in the first direction A and the third direction C. Referring to FIGS. 1 to 3, the device body 100 may include a middle frame 120 and a bottom cover 130. Referring to FIGS. 2 and 3, the bottom cover 130 may be connected to the middle frame 120 in the forward direction (the direction indicated by arrow B) of the second direction B, and surround the accommodating cavity 110 with the middle frame 120. The bottom cover 130 may be provided with a through hole 131 in communication with the accommodating cavity 110. The through hole 131 may have a stepped shape, with a large diameter section near the middle frame 120, and a small diameter section away from the middle frame 120.

In addition, referring to FIG. 2, the bottom part 280 of the first matching member 200 can be slidably disposed in the small diameter section of the through hole 131, and positions of the first matching member 200 in the first direction A and the third direction C are limited by the small diameter section of the through hole 131. The body part 240 of the first matching member 200 may be provided with a boss 290 which may abut against an inner bottom wall of the large diameter section of the through hole 131 when the first matching member 200 is in the first position, to limit a position of the first matching member 200 in the forward direction of the second direction B when the first matching member 200 is in the first position.

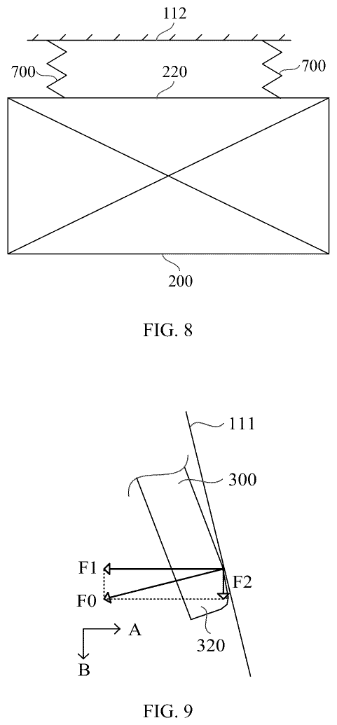

Furthermore, an elastic member (the spring leaf 300 shown in FIGS. 1, 2, 3 and 6, and the spring 700 shown in FIG. 8) may be disposed between the first matching member 200 and the accommodating cavity 110, and the elastic member may provide a force in the forward direction of the second direction B, so that when the first matching member 200 is in the first position shown in FIG. 2, the boss 290 of the first matching member 200 can abut against the inner bottom wall of the large diameter section of the through hole 131. Further, when a user pushes the first matching member 200 in the backward direction of the second direction B (the opposite direction to arrow B), the elastic member provides a resistance force to movement of the first matching member 200, and, after the user pushes the first matching member 200 to the second position shown in FIGS. 4 and 5 and removes his/her hand, provides a restoring force for the first matching member 200 to restore from the second position shown in FIG. 4 to the first position shown in FIG. 2.

Referring to FIG. 2, it is worth explaining that the first matching member 200 has a top end surface 220 and a bottom end surface 230 disposed oppositely in the second direction B, and the first matching member 200 has a side end surface 210 in the first direction A. The accommodating cavity 110 has an inner top surface 112 in the second direction B, and an inner side surface 111 in the second direction B.

FIG. 8 is a schematic diagram of a wearable device in the existing art. Referring to FIG. 8, in the existing art, the elastic member is a spring 700 which is disposed between the top end surface 220 of the first matching member 200 and the inner top surface 112 of the accommodating cavity 110. Further, the spring 700 is extendable along the second direction B. To obtain a sufficient restoring force generated by the spring 700, the spring 700 has a relatively long length in the second direction B, which requires larger space of the accommodating cavity 110 in the second direction B, resulting in a thicker device body 100.

To reduce the space occupied by the accommodating cavity 110 in the second direction B, by providing a spring leaf 300 between the side end surface 210 of the first matching member 200 and the inner side surface 111 of the accommodating cavity 110 in the wearable device provided in the embodiments of the present application, the spring leaf 300 may provide a reset decomposition force in the second direction B so that the space of the wearable device in the first direction A can be reasonably utilized, while the space of the wearable device in the second direction B can be reduced.

It is to be understood that the first matching member 200 is moved relative to the accommodating cavity 110, and to prevent the spring leaf 300 from falling off, the spring leaf 300 may be fixed to the first matching member 200 or the accommodating cavity 110. In other words, the spring leaf 300 has a fixed end 310 and a free end 320 along the first direction A, one of the side end surface 210 of the first matching member 200 and the inner side surface 111 of the accommodating cavity 110 is fixed to the fixed end 310 of the spring leaf 300, while the other of the side end surface 210 of the first matching member 200 and the inner side surface 111 of the accommodating cavity 110 abuts against the free end 320 of the spring leaf 300.

FIGS. 1, 2, 3 and 6 show an example in which the fixed end 310 of the spring leaf 300 is fixed to the side end surface 210 of the first matching member 200. Illustratively, when the side end surface 210 of the first matching member 200 is fixed to the fixed end 310 of the spring leaf 300, at least part of the inner side surface 111 of the accommodating cavity 110 abuts against the free end 320 of the spring leaf 300, and is inclined toward a forward direction of the second direction B and an outside of the accommodating cavity 110, thereby generating a restoring force in the second direction B.

Specifically, FIG. 9 is a diagram of resolution of forces at a free end 320 of the first matching member 200 shown in FIG. 4. Referring to FIG. 9, the spring leaf 300 receives a pressure force FO from the inner side surface 111 of the accommodating cavity 110 at a position where the free end 320 of the spring leaf 300 abuts against the inner side surface 111 of the accommodating cavity 110. Since the inner side surface 111 of the accommodating cavity 110 is inclined with respect to the second direction B, the pressure force FO may be resolved into a force F1 in the first direction A and a force F2 in the forward direction of the second direction B. The force F2 in the forward direction of the second direction B can move the spring leaf 300 and the first matching member 200 as a whole in the forward direction of the second direction B. In addition, the first matching member 200 may have spring leaves 300 on both sides of the first direction A, and the two spring leaves 300 receives forces F1 in the first direction A of equal magnitude and opposite directions.

In addition, to facilitate deformation of the spring leaf 300, referring to FIGS. 2, 4 and 6, optionally, the free end 320 of the spring leaf 300 is located on a side of the fixed end 310 of the spring leaf 300 in the forward direction of the second direction B. In other words, the spring leaf 300 is inclined in the same direction as at least part of the inner side surface 111 of accommodating cavity 110.

In addition, for convenience of processing, the spring leaf 300 and the first matching member 200 may be processed into a unitary piece through an integral molding process such as injection molding. In this case, to enhance the connection strength between the spring leaf 300 and the first matching member 200, referring to FIG. 6, a joint between the fixed end 310 of the spring leaf 300 and the first matching member 200 may be provided with an arc surface 600 having a center arranged in a forward direction of the second direction B. In other words, the spring leaf 300 is smoothly transited to the first matching member 200 through the arc surface 600.

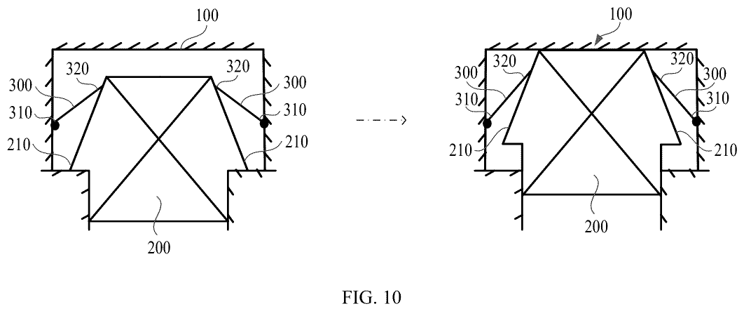

The above describes the arrangement of the spring leaf 300 shown in FIGS. 1, 2, 3 and 6, in which the fixed end 310 of the spring leaf 300 is fixed to the side end surface 210 of the first matching member 200. The following describes a case where the fixed end 310 of the spring leaf 300 is fixed to the inner side surface 111 of the accommodating cavity 110 with reference to FIG. 10.

FIG. 10 is a partial schematic diagram of another wearable device according to an embodiment of the present application, where the left shows a schematic diagram of the first matching member 200 in the first position, and the right shows a schematic diagram of the first matching member 200 in the second position. Referring to FIG. 10, illustratively, the fixed end 310 of the spring leaf 300 may be fixed to the inner side surface 111 of the accommodating cavity 110. At least part of the side end surface 210 of the first matching member 200 may abuts against the free end 320 of the spring leaf 300, and may be inclined toward a forward direction of the second direction B and an outside of the accommodating cavity 110, to provide a restoring force in the second direction B for the first matching member 200.

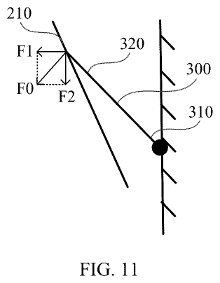

FIG. 11 is a diagram of resolution of forces at a free end 320 of the first matching member 200 shown in FIG. 10. Referring to FIG. 11, the side end surface 210 of the first matching member 200 receives a pressure force FO from the spring leaf 300 at a position where the free end 320 of the spring leaf 300 abuts against the side end surface 210 of the first matching member 200. Since the side end surface 210 of the first matching member 200 is inclined with respect to the second direction B, the pressure force FO may be resolved into a force F1 in the first direction A and a force F2 in the forward direction of the second direction B. The force F2 in the forward direction of the second direction B can move the first matching member 200 in the forward direction of the second direction B. In addition, at least two groups of spring leaves 300 may be provided and arranged on two sides of the first matching member 200 in the first direction A, respectively, so that the force F1 applied to the first matching member 200 in the first direction A can be counteracted. Each group of spring leaves 300 may include one or more spring leaves 300.

In addition, to facilitate deformation of the spring leaf 300, referring to FIG. 10, optionally, the free end 320 of the spring leaf 300 is located on a side of the fixed end 310 of the spring leaf 300 in a backward direction of the second direction B. In other words, the spring leaf 300 is inclined in the same direction as at least part of the side end surface 210 of the first matching member 200.

In addition, for convenience of processing, the spring leaf 300 and the inner side surface 111 of the accommodating cavity 110 (or the middle frame 120) may be processed into a unitary piece through an integral molding process such as injection molding. In this case, to enhance the connection strength between the spring leaf 300 and inner side surface 111 of the accommodating cavity 110, a joint between the fixed end 310 of the spring leaf 300 and the inner side surface 111 of the accommodating cavity 110 may be provided with an arc surface 600 having a center arranged in the backward direction of the second direction B. In other words, the spring leaf 300 is smoothly transited to the inner side surface 111 of the accommodating cavity 110 through the arc surface 600.

The terms “upper”, “lower” and the like are used for describing relative positions of the structures in the drawings, and are for clarity of description only instead of limiting the implementation scope of the present application, and any change or adjustment of the relative relationship between the structures without any substantial technical change should also be regarded as falling into the implementation scope of the present application.

It should be noted that: in this application, unless expressly stated or limited otherwise, a first feature “above” or “under” a second feature may refer to a case where the first and second features are in direct contact, or the first and second features are in indirect contact via an intermediary. Also, the first feature located “over”, “above” or “on” the second feature may refer to a case where the first feature is directly above or obliquely above the second feature, or simply indicate that the first feature is at a higher level than the second feature. The first feature “below”, “under” or “beneath” the second feature may refer to a case where the first feature is directly below or obliquely below the second feature, or simply indicates that the first feature is at a lower level than the second feature.

In addition, in this application, unless expressly stated or limited otherwise, the terms “mounted”, “connected”, “secured”, and the like are to be construed broadly and encompass, for example, both fixed and removable connection, or integral connection; or direct connection, indirect connection via an intermedium, or internal communication or interaction between two elements. The specific meaning of the above terms in the present application may be understood by those of ordinary skill in the art as the case may be.

In the description of the specification, reference to the description of terms “one embodiment”, “some embodiments”, “an exemplary embodiment”, “an example”, “a specific example” or “some examples” or the like means that a particular feature, structure, material, or characteristic described in connection with the embodiment or example is included in at least one embodiment or example of the present disclosure. In this specification, the schematic representations of the terms used above do not necessarily refer to the same embodiment or example. Furthermore, the particular feature, structure, material, or characteristic described may be combined in any suitable manner in any one or more embodiments or examples.

Finally, it should be noted that: the above embodiments are only used to illustrate the technical solutions of the present application, and not to limit the present application; although the present application has been described in detail with reference to the foregoing embodiments, it should be understood by those of ordinary skill in the art that: the technical solutions described in the foregoing embodiments may still be modified, or some or all of the technical features therein may be equivalently replaced; and these modifications or substitutions do not make the corresponding technical solution essentially depart from the scope of the technical solutions of the embodiments of the present application.

1: A wearable device comprising:
a device body provided with an accommodating cavity having an inner side surface in a first direction;
a first matching member slidably arranged in the accommodating cavity in a second direction and having a side end surface in the first direction;
a spring leaf disposed between the side end surface of the first matching member and the inner side surface of the accommodating cavity and configured to provide a reset decomposition force in the second direction; and
a device fixing band provided with a second matching member configured to run through the accommodating cavity in a third direction to be engaged with the first matching member wherein
the first direction, the second direction and the third direction are intersected in a pairwise manner.

2: The wearable device of claim 1, wherein the spring leaf has a fixed end and a free end along the first direction, one of the side end surface of the first matching member and the inner side surface of the accommodating cavity is fixed to the fixed end of the spring leaf, while the other of the side end surface of the first matching member and the inner side surface of the accommodating cavity abuts against the free end of the spring leaf; and
the one of the side end surface of the first matching member and the inner side surface of the accommodating cavity which abuts against the free end of the spring leaf is inclined relative to the second direction.

3: The wearable device of claim 2, wherein when the side end surface of the first matching member is fixed to the fixed end of the spring leaf, at least part of the inner side surface of the accommodating cavity abuts against the free end of the spring leaf, and is inclined toward a forward direction of the second direction and an outside of the accommodating cavity.

4: The wearable device of claim 3, wherein the free end (320) of the spring leaf is located on a side of the fixed end of the spring leaf in the forward direction of the second direction.

5: The wearable device of claim 3, wherein the spring leaf and the first matching member are processed into a unitary piece through an integral molding process.

6: The wearable device of claim 5, wherein a joint between the fixed end of the spring leaf and the first matching member is provided with an arc surface having a center arranged in a forward direction of the second direction.

7: The wearable device of claim 2, wherein when the inner side surface of the accommodating cavity is fixed to the fixed end of the spring leaf, at least part of the side end surface of the first matching member abuts against the free end of the spring leaf, and is inclined toward a forward direction of the second direction and an outside of the accommodating cavity.

8: The wearable device of claim 7, wherein the free end of the spring leaf is located on a side of the fixed end of the spring leaf in a backward direction of the second direction, and the spring leaf is inclined in the same direction as the at least part of the side end surface of the first matching member

9: The wearable device of claim 1, wherein the first matching member includes a body part and a beam part, the body part has an opening at an end in the second direction, and the beam part extends in the first direction to be disposed into the opening in the body part and forms a through slot with the body part; and
the second matching member is configured to run through the through slot of the first matching member to be engaged with the beam part

10: The wearable device of claim 9, wherein an end surface of the beam part away from the through slot is provided with a reinforcing rib extending in the first direction.
